(19) United States
(12) Patent Application Publication
(10) Pub. No.: US 2026/0358448 A1
(43) Pub. Date: Nov. 12, 2026

(54) METHOD FOR DETERMINING AN OPTIMIZED VALUE OF AT LEAST ONE MR PROTOCOL PARAMETER

(71) Applicant: Siemens Healthineers AG, Forchheim (DE)

(72) Inventors: Christian Meixner, Erlangen (DE); Lena Gast, Erlangen (DE); Max Brockmüller, Erlangen (DE)

(21) Appl. No.: 19/670,737

(22) Filed: May 7, 2026

(30) Foreign Application Priority Data
May 8, 2025 (DE) 10 2025 117 712.0

(51) Int. Cl. G01R 33/28; G01R 33/48; G01R 33/54

(52) U.S. Cl. CPC G01R 33/288; G01R 33/4828; G01R 33/543

(57) ABSTRACT

A computer-implemented method for determining an optimized value of at least one MR protocol parameter of a plurality of MR protocol parameters to carry out an MR measurement on a subject. The method includes providing an initial value of the at least one MR protocol parameter for the MR measurement, calculating a respective MR signal for a number of tissue types of the subject based on values of the plurality of MR protocol parameters including the at least one initial value of the at least one MR protocol parameter, and calculating an averaged tissue type contrast over the number of tissue types for the values of the plurality of MR protocol parameters including the at least one initial value of the at least one MR protocol parameter. The method further includes determining the optimized value of the at least one MR protocol parameter, by minimizing a difference between an averaged tissue type contrast over the number of tissue types, based on the values of the plurality of MR protocol parameters and in each case including varied values for the at least one MR protocol parameter, and an averaged tissue type contrast over the number of tissue types, based on the values of the plurality of MR protocol parameters including the initial value of the at least one MR protocol parameter, wherein the determination of the optimized value takes place with a boundary condition such that a specific absorption rate calculated with the optimized value for the at least one MR protocol parameter is less than or equal to a limit value for the specific absorption rate for the subject when the MR measurement is performed.

### CROSS REFERENCE TO RELATED APPLICATIONS

The application claims the benefit of DE 10 2025 117 712.0 filed on May 8, 2025, which is hereby incorporated by reference in its entirety.

### FIELD

Embodiments relate to a method for determining an optimized value of at least one magnetic resonance protocol parameter and a magnetic resonance system.

### BACKGROUND

For magnetic resonance measurements, an averaged specific absorption rate (SAR) must remain below a predetermined limit value at a predetermined time interval in order to avoid damage to the patient, for example due to heating. The specific absorption rate is a measure of an amount of power deposited by a radio frequency field in a certain tissue mass. For example, the specific absorption rate may be influenced by a plurality of MR protocol parameters, such as by way of example an RF frequency, an amplitude of a radio frequency excitation (B1 field) and thus a flip angle and/or a repetition rate of radio frequency excitations and thus a repetition time TR.

In this way the specific absorption rate SAR may serve as an indirect measure to monitor tissue heating by applying radio frequency excitations or RF pulses, which may lead to injuries to patients. In order to limit global tissue heating to a maximum of 0.5 °C in normal operating mode, the MR measurement must comply with certain limit values for the specific absorption rate. If an excessive energy deposition, as a result of which SAR limit values are exceeded, is to be expected during an MR measurement, values of MR protocol parameters must be adjusted.

The averaged specific absorption rate with respect to a whole body of the patient, the so-called whole-body SAR, may be ascertained before the actual measurement by dividing an expected power absorbed in the patient by the mass of the patient.

By a reference radio frequency excitation (adjustment), an amplitude for the radio frequency excitation which corresponds to a desired flip angle may be ascertained before the actual examination. With this amplitude, time-controlled pulses of an MR measurement may be scaled. An average power of the corresponding radio frequency excitations to be emitted may be predetermined here from. A coil power dissipation remaining in the transmit coil may be deducted from this power in order to determine an active power absorbed in the patient. The whole-body SAR is produced divided by the mass of the patient. In this way the power required for the reference pulse and thus the resulting SAR depends on the constitution of the patient.

When an MR protocol is created for an MR measurement, the MR protocol parameters of the MR protocol may be set according to a predetermined MR protocol optimization method in such a way that an optimal image may be expected. For example, a selected number of layers, an examination duration and the flip angle have a significant influence on the required average radio frequency power, which in turn determines the required SAR. For some patients, the power of the radio frequency excitation of the reference pulse may be particularly high for a predetermined flip angle. This may result in a high predicted SAR value for the MR protocol in question and lie above a permissible limit value.

In order for the examination to be able to be initiated or continued in accordance with the MR protocol, MR protocol parameters which allow the MR protocol to be carried out in compliance with the permissible limit value must be ascertained. Possible adjustments may be automatically provided to an operator of the MR system as suggestions for modification of at least one MR protocol parameter, but it cannot be assumed that an expected image quality of the MR measurement with modified MR protocol parameters will be guaranteed.

These suggestions to modify at least one MR protocol parameter may essentially relate to a desired flip angle and/or repetition time TR and/or pulse shape of the RF excitation. Different pulse shapes may also cause different specific absorption rates.

If the examination subject has implants, limit values for the specific absorption rate may be significantly lower than for MR measurements without implants.

If values of MR protocol parameters of an MR protocol, such as flip angle or repetition time, are restricted by an operator of the MR system towards a lower specific absorption rate, an MR measurement result, such as an MR image for instance, may have reduced contrast differences compared to the original MR protocol because these parameters and other parameters such as an echo time (TE) for instance are highly interdependent. Thus, the image impression may differ from the originally desired one if values of the MR protocol parameters are adjusted. Typically, only values of individual MR protocol parameters may be manually selected successively within predetermined limits. This means that, for example, if only the flip angle is initially reduced to a minimum value without bringing the specific absorption rate below the limit value, the repetition time TR may be extended in a further manual sequence in order to fall below the limit value for the specific absorption rate. As a result, it may not be possible to achieve an optimized setting of the values of the MR protocol parameters, which could be achieved, for example, with a slight reduction in the flip angle with a simultaneous slight increase in the repetition time TR.

Thus, there is a need to determine an optimized value of at least one MR protocol parameter while adhering to limit values for the specific absorption rate.

### BRIEF SUMMARY AND DESCRIPTION

The scope of the present disclosure is defined solely by the claims and is not affected to any degree by the statements within this summary. The present embodiments may obviate one or more of the drawbacks or limitations in the related art. Independent of the grammatical term usage, individuals with male, female or other gender identities are included within the term.

A first aspect relates to a computer-implemented method for determining an optimized value of at least one MR protocol parameter of a plurality of MR protocol parameters for carrying out an MR measurement on a subject, including the following steps. This method may be carried out by a computing unit, which is for example a part of a control unit of a magnetic resonance system or a magnetic resonance tomography system.

Depending on the scope of work, an MR measurement may be adapted for the MR measurement by parameters for different MR sequence types. A typical MR sequence (imaging sequence) consists of a package of short-duration RF pulse sequences that, together with a sequence of magnetic field gradients, cause a selected manipulation of nuclear magnetic resonance. The MR signals generated in this way may be detected by an RF antenna. Examples of an MR sequence type are gradient echo sequences or spin echo sequences, which may also be varied, e.g. according to the area of the body to be examined, with sequence cycles and parameters used. Typically, multiple MR sequences are applied in order to carry out a complete MR measurement of a subject. In addition to sequences of RF excitations and gradient sequences, an MR sequence may include other parameters of the MR system and/or the respective examination or MR measurement.

A certain MR sequence or a compilation of MR sequences to examine a specific tissue and/or body part, as well as certain diseases, may be referred to as an MR protocol. An MR protocol may be intended to define an MR measurement of the subject to be examined by an MR system. The MR protocol may include at least one MR protocol parameter. Thus, MR protocol parameters or magnetic resonance protocol parameters may be used for an MR measurement or for a magnetic resonance scan in order to define the respective MR measurement and/or adapt it to the subject being examined. The respective adaptation or definition may take place with a plurality of MR protocol parameters, for example 10 to 200, further for example 20-50 protocol parameters, by defining values for the respective MR protocol parameters.

In one step of the method, an initial value of the at least one MR protocol parameter is provided for the MR measurement. The initial value of the at least one MR protocol parameter and/or a selection of the at least one MR protocol parameter may be carried out manually by a user of a magnetic resonance system using an interface to the magnetic resonance system with which the MR measurement is carried out. Such an interface may include an operating terminal having a display unit, for example a monitor, and an input unit, for example a keyboard, a computer mouse, and/or a microphone. Alternatively or in addition, the initial value of the at least one MR protocol parameter and/or the selection of the at least one MR protocol parameter may be provided by the computing unit, for example by a database, and/or an MR protocol parameter and/or MR protocol parameter value proposed by the computing unit may be selected and/or modified by the user.

In a further step, a respective MR signal is calculated for a number of tissue types of the subject, based on values of the plurality of MR protocol parameters including the initial value of the at least one MR protocol parameter, for example by a computing unit, for example by simulation.

In a further step, an averaged tissue type contrast is calculated over the number of tissue types for the values of the plurality of MR protocol parameters including the initial value of the at least one MR protocol parameter, for example by the computing unit.

In a further step, an optimized value of the at least one MR protocol parameter is determined by minimizing a difference, for example by the computing unit.

The difference results from an averaged tissue type contrast over the number of tissue types, based on the values of the plurality of MR protocol parameters and each including varied values for the at least one MR protocol parameter, and an averaged tissue type contrast over the number of tissue types based on the values of the plurality of MR protocol parameters including the initial value of the at least one MR protocol parameter.

Here a specific absorption rate for the subject is less than or equal to a limit value for the specific absorption rate for the subject when carrying out the MR measurement if the specific absorption rate is calculated based on the optimized value for the at least one MR protocol parameter. In other words, the minimization of the difference occurs below this boundary condition for the specific absorption rate.

Alternatively or in addition, this boundary condition may include a maximum recording time and/or a minimum resolution and/or a limit value for an applied RF power and/or a limit value for the applied gradient switching activity and/or a limit value for gradient power, for example with respect to respective gradient axes, in order to avoid wear and damage to components of the magnetic resonance system.

In other words, this method may be used to carry out an MR measurement in which the specific absorption rate for the subject is less than or equal to the limit value for the specific absorption rate. Here the averaged tissue type contrast with the optimized value for the at least one MR protocol parameter, based on an optimization method to minimize the difference, is as equal as possible to the originally averaged tissue type contrast with the provided initial values of the at least one MR protocol parameter. The plurality of MR protocol parameters including the provided initial values of the at least one MR protocol parameter may correspond to an original MR protocol.

Advantageously, this method is independent of an MR sequence used and a desired tissue type contrast or image contrast, and does not require any interaction or previous experience of the operator of the MR system.

For example, the MR protocol parameter may include a flip angle and/or a repetition time TR and/or an echo time TE and/or a pulse shape and/or other MR protocol parameters for the optimization.

The MR signal may be approximated, for example, by a Bloch simulation, carried out for example numerically, wherein the number of tissue types for the body region to be scanned are considered. For example, the body region selected during patient registration may be used to select which tissue types are to be simulated, or an image recognition algorithm/AI algorithm may evaluate localizer data that has already been recorded.

Here the following function (Formula 1) is to be minimized for a number of tissue types:

$${min}_{prot} {‖ {Contrast}_{prot} - {Corntrast}_{{prot}_{initial}} ‖}_{2}$$

Here the Contrast with the index prot stands for a function that determines the averaged tissue type contrast, according to an MR protocol, which determines the plurality of MR protocol parameters including the varied value of the at least one MR protocol parameter. The Contrast with the index prot (initial) stands for a function that determines the averaged tissue type contrast, according to an MR protocol, which determines the plurality of MR protocol parameters including the initial value of the at least one MR protocol parameter. The difference between these two averaged tissue type contrasts is minimized in Formula 1 with a square norm for an optimal value of the at least one MR protocol parameter for the corresponding MR protocol.

In the minimization described above, the following boundary condition (Formula 2) is to be met:

SAR(prot)<SARₗᵢₘᵢₜ

In Formula 2, SAR (prot) stands for a function which determines the specific absorption rate for the subject and for an optimized MR protocol, i.e. the plurality of MR protocol parameters including the optimized value of the at least one MR protocol parameter. SAR Index (limit) stands for the limit value for the specific absorption rate for the subject when the corresponding MR measurement is carried out.

Fulfillment of the boundary condition (Formula 2) may ensure that SAR limit values (SARₗᵢₘᵢₜ) according to IEC 60601-2-33 are not exceeded by the respective MR protocol (prot). The SAR limit value may refer here to limit values for whole-body SAR, partial-body SAR, and/or head SAR. Alternatively or in addition, the limit value may refer to other variables of the MR measurement.

Advantageously, an average power of a radio frequency excitation signal for the determination of the optimized value of the at least one MR protocol parameter, based on an average power of a radio frequency excitation signal of an initial MR protocol measured on the subject, may be standardized with an SAR factor to a permissible average power. Here the SAR factor indicates a ratio of at least one limit value for the specific absorption rate to at least one specific absorption rate which is determined for the subject by the adjustment measurement and/or the model calculation. This is explained in more detail below.

By limiting the average power of the radio frequency excitation signal to a permissible value by the SAR factor, the boundary condition for the specific absorption rate may be taken into account by the average power of the frequency excitation signal when the optimal value of the at least one MR protocol parameter is determined.

The power may be averaged over a first time window of 10 seconds and a second time window of 6 minutes. The average power is then defined over the time window that results in the larger value.

Since the specific absorption rate (SAR) is proportional to a power of the radio frequency excitation signal B₁², Formula 3 applies accordingly:

SAR∝B₁²

Therefore, the boundary condition corresponding to Formula 2, which expresses that the specific absorption rate for the MR measurement must be less than a limit value for the specific absorption rate, may be formulated in an equivalent way to a power of the radio frequency excitation signal B₁² with Formula 4:

$${B}_{1 , avg}^{2} ( prot ) < {B}_{1 , avg , limit}^{2}$$

Here

$${B}_{1 , avg}^{2} prot$$

is an averaged, square electromagnetic field B₁, or radio frequency excitation signal B₁ for the respective MR protocol (prot), and thus corresponding to an area under RF pulses of the electromagnetic field B₁ for the MR protocol. This must apply in accordance with the limit value for the specific absorption rate SAR for averaging over at least two SAR-relevant time windows of 10 s and 6 min. Depending on the MR protocol (prot), B_{1,avg}prot may be dependent on a pulse shape of the radio frequency excitation, a flip angle, and a repetition time TR of the radio frequency excitation.

By an adjustment measurement for the subject and/or a model calculation for the subject, it is possible to determine how high the averaged, square electromagnetic field

$${B}_{1 , avg}^{2} prot$$

of a respective MR protocol may be for the minimization according to Formula 1 in order to comply with the limit value for the specific absorption rate.

According to Formula 5:

$${B}_{1 , avg , limit}^{2} = {B}_{1 , avg}^{2} ( {prot}_{initial} ) \cdot {min}_{a} ( \frac{{SAR}_{limit , a}}{{SAR}_{initial , a}} )$$

a maximum power of the radio frequency excitation signal

$${B}_{1 , avg , limit}^{2}$$

for a permissible MR protocol, based on a power of a radio frequency excitation signal

$${B}_{1 , avg}^{2} ( {prot}_{initial} )$$

with an MR protocol where the power is unacceptably high, is to be reduced by an SAR factor (Formula 6):

$${min}_{a} ( \frac{{SAR}_{limit , a}}{{SAR}_{initial , a}} )$$

The SAR factor is determined from a minimum over different SAR aspects a of a ratio of limit values for the specific absorption rate SAR_{limit,a} for the respective SAR aspects a, to initially determined specific absorption rates SAR_{initial,a} for the respective SAR aspects a. Here the initial specific absorption rates may be measured with short radio frequency excitation signals for the subject and/or determined for the subject by model calculations.

Here the respective MR protocol may have the respective values of the plurality of MR protocol parameters.

In other words, the minimum to be determined mina must be determined over a group of SAR aspects a to be monitored (a=whole-body SAR, partial-body SAR, head SAR, etc.) as well as the two averaging periods: 10 s and 6 min in order to determine the maximum for the power of the radio frequency excitation signal

$${B}_{1 , avg , limit}^{2} .$$

In addition, other boundary conditions such as e.g. a maximum TR, minimum or maximum resolution may be applied for minimization according to Formula 1.

Advantageously, when the optimized value of the at least one MR protocol parameter is determined, this may only be varied within predetermined limit values, wherein the predetermined limit values include, for example, a maximum repetition time.

The difference in the averaged tissue type contrasts may be minimized advantageously below a boundary condition when the optimized value of the at least one MR protocol parameter is determined such that a certain repetition time, respectively recording time is adhered to or a minimum resolution is guaranteed.

For optimization, i.e. to determine the minimum of the differences in tissue type contrasts, conventional optimization algorithms, such as conjugate gradient methods, trust-region methods or inner-point methods, etc., which are known to the skilled person, may be used.

Here the tissue type contrast with the variable Contrast may be determined by averaging over differences in MR signals Sᵢ of the respective tissue type i from an MR signal S̅ averaged over the number N of tissue types according to the following Formula 7:

$$Contrast : = \sqrt{\frac{1}{N} {\sum }_{i}^{N} {( {S}_{i} - \overline{S} )}^{2}}$$

and/or by averaging differences in the MR signals Si; Sj of two different types of tissue i, j according to the following Formula 8:

$$Contrast : = \sqrt{\frac{1}{N} {\sum }_{i}^{N - 1} {\sum }_{J > I}^{N} - {S}_{i} - {S}_{j} {-}^{2}}$$

Advantageously, the respective MR signal of the number of tissue types may be calculated by an, for example numerical, Bloch simulation on the basis of a radio frequency excitation signal and a magnetic field gradient for the MR measurement of the subject and MR properties of the number of tissue types.

The MR signals S_{1≤i≤N} may be determined for the number N of tissues i according to the following Formula 9:

Sᵢ=BlochSim([pulse,gradient_{xyz}],T₁,T₂)_{tissue i′}

Here BlochSim is a function based on a Bloch simulation.

With Formula 10:

[pulse,dgradient_{xyz}]=SeqSim(prot)
a temporal pulse and gradient sequence SeqSim (prot) may be

characterized on the basis of the protocol parameters prot set. Initial protocol parameters or protocol parameters originally set by the user correspond to the variable protᵢₙᵢₜᵢₐₗ. This temporal sequence may be ascertained by a complete or partial simulation of the MR sequence, e.g. only a fraction of the required repetitions. Here, pulse may be a variable for the respective pulse curve of the radio frequency excitation signal and gradient _{xyz} may be the respective gradient sequence of the magnetic field gradient for the MR measurement of the subject in the spatial directions x, y, and z.

For example, the tissue type contrast may be calculated on the basis of a complete or partial repetition of the simulation of MR sequences defined by the variety of MR protocol parameters.

Typical properties of the tissue types with the parameters for the Bloch simulation, such as: T1, the spin-lattice relaxation time for the respective tissue type; T2, the spin-spin relaxation time for the respective tissue type; T2* the effective spin-spin relaxation time may be provided for a respective region of the subject before the calculation, for example by a database. In addition or alternatively, the number of tissue types used may be provided correspondingly for the respective calculation by the Bloch simulation. This may also affect respective body regions, or regions of the subject, for the MR measurement. In Formula 9, the spin-spin relaxation time T2 may alternatively be used by the effective spin-spin relaxation time T2*.

The protocol parameters determined by way of this optimization may be used automatically or with the consent of the user of the MR system for the subsequent MR measurement. By definition, the image contrast is at least largely preserved and at the same time the SAR limits are complied with.

Alternatively or in addition, the respective MR signal of the number of tissue types may be calculated using a neural network and/or using an extended phase graphs method and/or using a lookup table based on the MR properties of the number of tissue types. Here the calculation may be based on a radio frequency excitation signal and/or a magnetic field gradient.

The calculation of the tissue contrast based on extended phase graphs is explained, for example, in: Endres et al., Phase distribution graphs for fast, differentiable, and spatially encoded Bloch simulations of arbitrary MRI sequences, MRM, 2024. The advantage of this method is a faster calculation than using Bloch simulation.

Lookup tables may have pre-calculated values for frequently required tissue contrasts and sequence parameter combinations. Intermediate values may be interpolated. The lookup table could already be filled with values on delivery of the MR system, but could also be dynamically adapted to usage behavior during use. This would avoid simulation, for example by Bloch simulation or extended phase graphs, and thus enable faster optimization.

For example, the method for determining the optimized MR measurement value of the subject may be carried out by a magnetic resonance system, based on the plurality of MR protocol parameters, including the optimized value for the at least one MR protocol parameter. Here the MR system may have a computing unit that is set up to carry out the method.

Advantageously, the method for determining optimized values may be carried out with a group of MR protocol parameters, wherein initial values are provided for members of the group of MR protocol parameters in each case. In a step of the method, a respective MR signal for a number of tissue types of the subject is calculated on the basis of values of the plurality of MR protocol parameters including the initial values of the group of MR protocol parameters. In a further step, an averaged tissue type contrast is calculated over the number of tissue types for the values of the plurality of MR protocol parameters including the initial values of the group of MR protocol parameters. In a further step, the optimized values of the group of MR protocol parameters are determined by minimizing a difference between an averaged tissue type contrast over the number of tissue types, on the basis of the values of the plurality of MR protocol parameters and in each case including varied values for the group of MR protocol parameters, and an averaged tissue type contrast over the number of tissue types on the basis of the values of the plurality of MR protocol parameters including the initial values of the group of MR protocol parameters. Here the optimized values are determined with a boundary condition such that a specific absorption rate for the subject calculated with the optimized values for the group of MR protocol parameters is less than or equal to a limit value for the specific absorption rate for the subject when carrying out the MR measurement.

As a result, using the method the MR measurement may advantageously determine parameter values of the group of MR protocol parameters in such a way that the specific absorption rate for the subject is below the limit value for the specific absorption rate when the MR measurement is carried out. Thus, the optimization result may be improved, as different measurement parameter combinations are possible and/or further boundary conditions may be taken into account for the optimization. By applying the method to a group of MR protocol parameters, a difference between the averaged tissue type contrast with the optimized values for the group of MR protocol parameters and the averaged tissue type contrast with initial values for the group of MR protocol parameters may become particularly small.

For example, the group of MR protocol parameters for the optimization described above may include a flip angle and/or a repetition time TR and/or an echo time TE and/or a pulse shape and/or other MR protocol parameters.

According to one aspect, the method may have the additional step of determining a specific absorption rate based on the initial value for the at least one MR protocol parameter. The method steps described above for determining the optimized value of the at least one MR protocol parameter may then be carried out if the specific absorption rate determined by the initial value of the at least one MR protocol parameter is greater than the limit value for the specific absorption rate for the subject.

When the MR measurement is carried out, the limit value for the specific absorption rate for the subject may advantageously be determined on the basis of an adjustment measurement for the subject and/or a model calculation for the subject. The adjustment measurement may be carried out with a short radio frequency excitation signal so as not to exceed the specific absorption rate on the subject during the adjustment measurement.

In other words, the method may then be carried out when the specific absorption rate, which is determined with the initial value of the at least one MR protocol parameter, is greater than the limit value for the specific absorption rate. Here the specific absorption rate, which is based on the initial value of the at least one MR protocol parameter, may be determined for a specific subject, according to the prior art, on the basis of a prescan (adjustment or tune-up measurement) before the MR measurement of the specific subject. Alternatively or in addition, the specific absorption rate which is based on the initial value of the at least one MR protocol parameter may be determined for the specific subject by a comparison with reference values, which are based on specific properties of the subject.

The limit value for the specific absorption rate for the subject may depend on whether the MR measurement is carried out on the entire subject or only on parts of the subject or a head of the subject. Alternatively or in addition, the limit value for the specific absorption rate may depend on whether the subject or the relevant part of the subject have an implant.

The concept of determining may include calculating and/or measuring.

For example, the limit value for the specific absorption rate for the subject may refer to the whole subject or around a part of the subject or to a head of the subject, wherein the presence of an implant in the subject may reduce the limit value for the specific absorption rate.

The at least one MR protocol parameter may be a flip angle, or an amplitude of a radio frequency excitation of the MR measurement, and/or a repetition time TR, or a repetition rate of radio frequency excitation pulses of a radio frequency excitation signal of the MR measurement, and/or a pulse shape of the radio frequency excitation signal of the MR measurement, and/or a field of view and/or a layer position and/or a layer thickness and/or a layer orientation and/or an echo time and/or an echo spacing and/or repetition times.

For example, the method may provide for a subset of the plurality of protocol parameters or the plurality of protocol parameters to be optimized together. Here, the subset of the plurality may for example only include protocol parameters that are assessed as relevant in accordance with a target of an MR measurement.

According to one aspect, it is proposed that the respective MR signal of the number of tissue types be calculated by a Bloch simulation, for example based on a radio frequency excitation signal and/or a magnetic field gradient for the MR measurement of the subject and/or MR properties of the number of tissue types. For example, the Bloch simulation may be carried out numerically.

The radio frequency excitation signal of the MR measurement may have a temporal sequence of pulses. The magnetic field gradient of the MR measurement may vary in a temporal sequence.

Advantageously, the MR measurement may be carried out on a specific body region of the subject. The tissue types to be considered for the corresponding tissue type contrast and/or the MR properties for the respective body region may be predetermined and stored or saved, for example in a database, for example of a magnetic resonance system.

According to a further aspect, a magnetic resonance system or magnetic resonance tomography system is proposed for an MR measurement of a subject, having: a main magnet for generating an at least substantially static magnetic field; a gradient system for generating magnetic field gradients; a radio frequency antenna unit, or body coil, for generating a radio frequency excitation for the MR measurement; and a control device coupled to the main magnet, the gradient system and the radio frequency antenna unit, which is set up to control the magnetic resonance system for the MR measurement of the subject on the basis of a plurality of MR protocol parameters; and wherein a computing unit of the control unit is set up to carry out one of the methods described above for an MR measurement of a subject.

A computing unit may be understood to mean for example a data processing device that contains a processing circuit. The computing unit may therefore process data for example for the performance of arithmetic operations. This may also include operations to perform indexed access to an examination data structure, such as a lookup table (LUT). The computing unit may for example contain one or more computers, one or more microcontrollers and/or one or more integrated circuits, for instance one or more application-specific integrated circuits (ASIC), one or more field-programmable gate arrays (FPGA), and one or more systems on a chip (SoC). The computing unit may also contain one or more processors, for instance one or more microprocessors, one or more central processing units (CPU), one or more graphics processing units (GPU), and/or one or more signal processors, for example one or more digital signal processors (DSP). The computing unit may also include a physical or a virtual array of computers or other of the aforementioned units.

A magnetic resonance system is proposed to examine a subject, including: a controllable main magnet for generating an at least substantially static magnetic field and set up for the examination of the subject; a gradient system for generating magnetic field gradients; a radio frequency antenna unit body coil for generating a radio frequency excitation, which is set up for a magnetic resonance examination of the subject in interaction with the magnet; and a control unit coupled to the main magnet, the gradient system and the radio frequency antenna unit. The control unit may have a computing unit and be set up to control the magnetic resonance system for the examination of the subject on the basis of a plurality of protocol parameters. The computing unit may be set up to carry out one of the methods described above.

A computer program is proposed, which may be loaded for example directly into a memory of a control unit, including commands which, when the computer program is executed by a computer, cause it to execute one of the methods described above.

The computer program or computer program product may be configured in such a way that it may perform the method steps by the computing facility.

The computing facility may have the respective prerequisites, such as a corresponding RAM, a corresponding graphics card and/or a corresponding logic unit, so that the respective method steps may be performed.

An electronically readable data carrier with electronically readable control information stored thereon is proposed, which has at least one of the computer programs described above, wherein the control information is designed in such a way that it performs one of the methods described above for determining an optimized value in a control unit of a magnetic resonance system.

An electronically readable data carrier or storage unit may be configured as a volatile examination data memory, such as a dynamic random access memory (DRAM) or static random access memory (SRAM), or as a non-volatile examination data memory, such as a read-only memory (ROM), a programmable read-only memory (PROM), an erasable programmable read-only memory (EPROM), an electrically erasable programmable read-only memory (EEPROM), a flash memory or flash EEPROM, a ferroelectric random access memory (FRAM), a magnetoresistive random access memory (MRAM) or a phase-change random access memory (PCRAM).

It is proposed to use a computing unit to optimize a value of at least one MR protocol parameter of a plurality of MR protocol parameters to carry out an MR measurement of a subject, the computing unit being set up to carry out one of the methods described above to determine an optimized value of at least one MR protocol parameter.

### BRIEF DESCRIPTION OF THE FIGURES

FIG. 1 depicts a flowchart of a method for determining an optimized value of at least one MR protocol parameter according to an embodiment.

FIG. 2 depicts components of a magnetic resonance system according to an embodiment.

### DETAILED DESCRIPTION

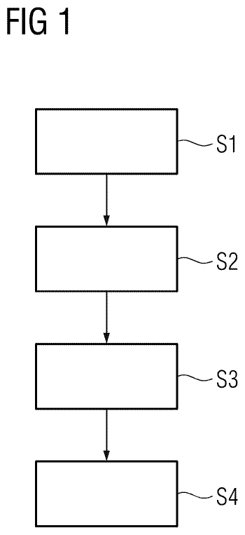

FIG. 1 shows a schematic outline of steps of a computer-implemented method for determining an optimized value of at least one MR protocol parameter of a plurality of MR protocol parameters for carrying out an MR measurement on a subject, which includes the following steps.

By a sequence of RF pulses and switched magnetic field gradients, nuclear magnetic spins may be excited, magnetic resonance may be induced, refocused, manipulated, and spatially or otherwise encoded to generate images of an MR measurement. A typical MR imaging sequence includes a package of short-duration RF pulse sequences that, together with a sequence of magnetic field gradients, cause a selected manipulation of nuclear magnetic resonance. The MR signals generated in this way may be detected by an RF antenna.

In a step S1, an initial value of the at least one MR protocol parameter is provided for the MR measurement. The initial value of the at least one MR protocol parameter and/or a selection of the at least one MR protocol parameter may be done manually by a user of a magnetic resonance system using an interface to the magnetic resonance system with which the MR measurement is carried out. Alternatively or in addition, the initial value of the at least one MR protocol parameter and/or the selection of the at least one MR protocol parameter may be provided by the computing unit, for example by a database, and/or an MR protocol parameter and/or MR protocol parameter value proposed by the computing unit may be selected and/or modified by the user.

In a further step S2, a respective MR signal is calculated for a number of tissue types of the subject, based on values of the plurality of MR protocol parameters including the initial value of the at least one MR protocol parameter.

In a further step S3, an averaged tissue type contrast is calculated over the number of tissue types for the values of the plurality of MR protocol parameters including the initial value of the at least one MR protocol parameter.

In a further step S4, an optimized value of the at least one MR protocol parameter is determined by minimizing a difference. The difference results from an averaged tissue type contrast over the number of tissue types, on the basis of the values of the plurality of MR protocol parameters and each including varied values for the at least one MR protocol parameter, and an averaged tissue type contrast over the number of tissue types on the basis of the values of the plurality of MR protocol parameters including the initial value of the at least one MR protocol parameter. Here a boundary condition is that a specific absorption rate for the subject is less than or equal to a limit value for the specific absorption rate for the subject while the MR measurement is being carried out if the specific absorption rate is calculated on the basis of the optimized value for the at least one MR protocol parameter.

Alternatively or in addition, this boundary condition may include a limit value for an applied RF power, a limit value for the applied gradient switching activity, a limit value for the gradient power, for example in respect of the gradient axes, in order to avoid wear and damage to components of the magnetic resonance system.

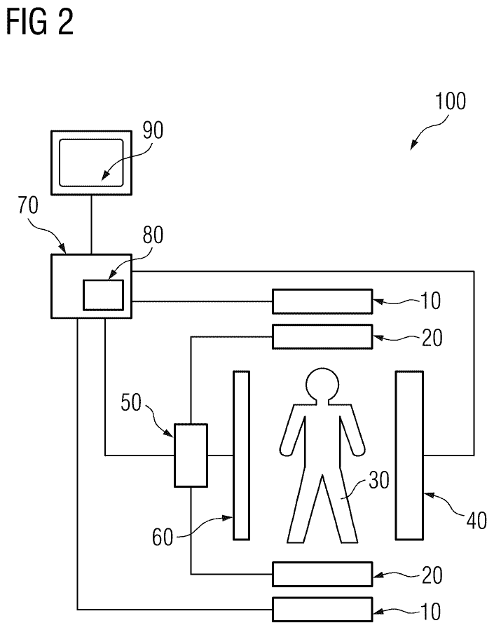

FIG. 2 shows a schematic outline of an MR system 100. The MR system 100 includes superconducting or resistive main magnet coils 10, so that an essentially uniform, temporarily constant main magnetic field B0 may be generated along a z axis by an examination volume.

The MR system 100 may apply a series of radio frequency excitation signals, or RF pulses, and switched magnetic field gradients to invert or excite nuclear magnetic spins, induce magnetic resonance, refocus magnetic resonance, manipulate magnetic resonance, spatially or otherwise encode magnetic resonance, saturate spins, and the like to perform an MR measurement for MR imaging.

By a gradient system 40, which is coupled with a controller 70, magnetic field gradients may be generated along the x, y, and z axes of an examination volume. The radio frequency excitation signals may be generated with a radio frequency system 50 and by radio frequency antenna units 20 in order to send RF pulses into the examination volume of a subject 80. Here the radio frequency component 20 is coupled with the radio frequency system 50 and the radio frequency system 50 is coupled with the controller 70 to control the radio frequency system 50. A typical MR imaging sequence may have a package of short-duration RF pulse sequences that, together with applied magnetic field gradients, achieve a selected manipulation of the nuclear spin resonance. The RF pulses may be used to saturate and excite a part of a subject 80 positioned in the examination volume and to reverse the magnetization in order to refocus the resonance or manipulate and select the resonance. MR signals may also be detected by the radio frequency antenna units 20.

To generate MR images of confined body regions or of general subjects 80, for example by parallel imaging, a local radio frequency antenna system 60 which is coupled with the radio frequency system 50 may be placed adjacent to the region 80 selected for imaging. Here the local radio frequency antenna system 60 may also be used to receive MR signals which are induced by RF transmissions via the radio frequency units 20.

The controller 70 is coupled with the main magnet 10, the radio frequency system 50, and the gradient system 40 and is set up to control the gradient system and the radio frequency antenna unit 20 to produce one of several imaging sequences, such as echo planar imaging (EPI), echo volume imaging, gradient and spin echo imaging, fast spin echo imaging, and the like.

The resulting MR signals may be picked up by the radio frequency unit 20 and/or by the local radio frequency antenna system 60 and provided to a computing unit 80 which is coupled with the radio frequency antenna system 50 in order to reconstruct an image representation. The MR image may show a planar section through the patient, an arrangement of parallel planar sections, a three-dimensional volume, or the like. By an interface 90 coupled with the controller 70 and the computing unit 80, a user of the MR system 100 may select or change MR protocol parameters. The computing unit 80 may be set up to perform computer-implemented methods.

It is to be understood that the elements and features recited in the appended claims may be combined in different ways to produce new claims that likewise fall within the scope of the present disclosure. Thus, whereas the dependent claims appended below depend from only a single independent or dependent claim, it is to be understood that the dependent claims may, alternatively, be made to depend in the alternative from any preceding or following claim, whether independent or dependent, and that such new combinations are to be understood as forming a part of the present specification.

While the present disclosure has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A computer-implemented method for determining an optimized value of at least one magnetic resonance (MR) protocol parameter of a plurality of MR protocol parameters for carrying out an MR measurement on a subject, the method comprising:
providing an initial value of the at least one MR protocol parameter for the MR measurement;
calculating a respective MR signal for a number of tissue types of the subject based on the values of the plurality of MR protocol parameters including the at least one initial value of the at least one MR protocol parameter;
calculating an averaged tissue type contrast over the number of tissue types for the values of the plurality of MR protocol parameters including the at least one initial value of the at least one MR protocol parameter;
determining the optimized value of the at least one MR protocol parameter, by minimizing a difference between:
an averaged tissue type contrast over the number of tissue types, based on the values of the plurality of MR protocol parameters and in each case including varied values for the at least one MR protocol parameter, and
an averaged tissue type contrast over the number of tissue types based on the values of the plurality of MR protocol parameters including the initial value of the at least one MR protocol parameter;
wherein the determination of the optimized value takes place with a boundary condition such that a specific absorption rate calculated with the optimized value for the at least one MR protocol parameter is less than or equal to a limit value for the specific absorption rate for the subject when the MR measurement is carried out.

2. The method of claim 1, wherein the MR measurement of the subject is carried out by a magnetic resonance system, based on the plurality of MR protocol parameters including the optimized value for the at least one MR protocol parameter.

3. The method of claim 1, further comprising:
determining a specific absorption rate based on the initial value for the at least one MR protocol parameter;
wherein the specific absorption rate which is determined with the initial value of the at least one MR protocol parameter is greater than the limit value for the specific absorption rate for the subject.

4. The method of claim 1, wherein the at least one MR protocol parameter of the MR measurement comprises at least one of: a flip angle of a radio frequency excitation signal of the MR measurement; a repetition time of the radio frequency excitation signal of the MR measurement; or a pulse shape of the radio frequency excitation signal of the MR measurement.

5. The method of claim 1, wherein the MR measurement has a temporal sequence of radio frequency excitation signals and/or a temporal sequence of magnetic field gradients, and wherein the respective MR signal of the number of tissue types is calculated by an, for example numerical, Bloch simulation of the MR measurement of the subject and MR properties of the number of tissue types.

6. The method of claim 1, wherein the respective MR signal of the number of tissue types is calculated by a neural network and/or by an extended phase graphs method and/or by a lookup table based on MR properties of the number of tissue types.

7. The method of claim 1, wherein the tissue type contrast is determined by averaging over differences of the MR signals of the respective tissue type from an MR signal averaged over the number of tissue types; and/or by an averaging of differences of MR signals of two different tissue types in each case.

8. The method of claim 1, wherein the limit value for the specific absorption rate for the subject is determined based on an adjustment measurement and/or a model calculation for the subject when the MR measurement is carried out.

9. The method of claim 1, wherein an average power of a radio frequency excitation signal for the determination of the optimized value of the at least one MR protocol parameter, starting from an average power of a radio frequency excitation signal of an initial MR protocol measured on the subject, is standardized with an SAR factor to a permissible average power, wherein the SAR factor specifies a ratio of at least one limit value for the specific absorption rate to at least one specific absorption rate which is determined for the subject by the adjustment measurement and/or the model calculation.

10. The method of claim 1, wherein when the optimized value of the at least one MR protocol parameter is determined, this is only varied within predetermined limit values, wherein the predetermined limit values comprise for example a maximum repetition time.

11. The method of claim 1, wherein the method is carried out to determine optimized values of a group of MR protocol parameters, wherein initial values are provided for the group of MR protocol parameters in each case;
calculating a respective MR signal for a number of tissue types of the subject based on values of the plurality of MR protocol parameters including the initial values of the group of MR protocol parameters;
calculating an averaged tissue type contrast over the number of tissue types for the values of the plurality of MR protocol parameters including the initial values of the group of MR protocol parameters;
determining the optimized values of the group of MR protocol parameters, by minimizing a difference between an averaged tissue type contrast over the number of tissue types, based on the values of the plurality of MR protocol parameters and in each case including varied values for the group of MR protocol parameters, and an averaged tissue type contrast over the number of tissue types based on the values of the plurality of MR protocol parameters including the initial values of the group of MR protocol parameters,
wherein the determination of the optimized value is carried out with a boundary condition such that a specific absorption rate for the subject, calculated with the optimized values for the group of MR protocol parameters, is less than or equal to a limit value for the specific absorption rate for the subject when the MR measurement is carried out.

12. The method of claim 1, wherein the MR measurement is to be carried out on a certain body region of the subject, and wherein the tissue types to be considered for the tissue type contrast and their MR properties are predetermined for the body region and stored for example in a database.

13. A magnetic resonance (MR) system for an MR measurement on a subject, the MR system comprising:
a main magnet for generating an at least substantially static magnetic field;
a gradient system for generating magnetic field gradients;
a radio frequency antenna unit for generating a radio frequency excitation signal for the MR measurement; and
a control unit which is coupled with the main magnet, the gradient system, and the radio frequency antenna unit, and is set up to control the MR system for the MR measurement of the subject based on a plurality of MR protocol parameters; and wherein a computing unit of the control unit is configured to:
provide an initial value of at least one MR protocol parameter for the MR measurement;
calculate a respective MR signal for a number of tissue types of the subject based on the values of the plurality of MR protocol parameters including the at least one initial value of the at least one MR protocol parameter;
calculate an averaged tissue type contrast over the number of tissue types for the values of the plurality of MR protocol parameters including the at least one initial value of the at least one MR protocol parameter;
determine an optimized value of the at least one MR protocol parameter, by minimizing a difference between an averaged tissue type contrast over the number of tissue types, based on the values of the plurality of MR protocol parameters and in each case including varied values for the at least one MR protocol parameter and an averaged tissue type contrast over the number of tissue types based on the values of the plurality of MR protocol parameters including the initial value of the at least one MR protocol parameter;
wherein the determination of the optimized value takes place with a boundary condition such that a specific absorption rate calculated with the optimized value for the at least one MR protocol parameter is less than or equal to a limit value for the specific absorption rate for the subject when the MR measurement is carried out.

14. A non-transitory computer implemented storage medium that stores machine-readable instructions executable by at least one processor for determining an optimized value of at least one magnetic resonance (MR) protocol parameter of a plurality of MR protocol parameters for carrying out an MR measurement on a subject, the machine-readable instructions when carried out cause the at least one processor to:
provide an initial value of the at least one MR protocol parameter for the MR measurement;
calculate a respective MR signal for a number of tissue types of the subject based on the values of the plurality of MR protocol parameters including the at least one initial value of the at least one MR protocol parameter;
calculate an averaged tissue type contrast over the number of tissue types for the values of the plurality of MR protocol parameters including the at least one initial value of the at least one MR protocol parameter;
determine the optimized value of the at least one MR protocol parameter, by minimizing a difference between:
an averaged tissue type contrast over the number of tissue types, based on the values of the plurality of MR protocol parameters and in each case including varied values for the at least one MR protocol parameter, and
an averaged tissue type contrast over the number of tissue types based on the values of the plurality of MR protocol parameters including the initial value of the at least one MR protocol parameter;
wherein the determination of the optimized value takes place with a boundary condition such that a specific absorption rate calculated with the optimized value for the at least one MR protocol parameter is less than or equal to a limit value for the specific absorption rate for the subject when the MR measurement is carried out.
